(19) United States
(12) Patent Application Publication
(10) Pub. No.: US 2024/0188285 A1
(43) Pub. Date: Jun. 6, 2024

(54) SEMICONDUCTOR DEVICE

(71) Applicant: SAMSUNG ELECTRONICS CO., LTD., Suwon-si (KR)

(72) Inventors: Youngjun KIM, Suwon-si (KR); Hyosub KIM, Suwon-si (KR); Junhyeok AHN, Suwon-si (KR)

(21) Appl. No.: 18/509,539

(22) Filed: Nov. 15, 2023

(30) Foreign Application Priority Data
Dec. 2, 2022 (KR) 10-2022-0166329

(51) Int. Cl. H10B 12/00

(52) U.S. Cl. CPC H10B 12/482; H10B 12/02; H10B 12/315

(57) ABSTRACT

The semiconductor device includes an active pattern; a gate structure in an upper portion of the active pattern; a bit line structure on the active pattern, the bit line structure including a first metal; a first spacer on a sidewall of the bit line structure, the first spacer including an oxide of a second metal that has an ionization energy smaller than that of the first metal; a second spacer on an outer sidewall of the first spacer, the second spacer including an oxide of a third metal; a third spacer on a lower portion of an outer sidewall of the second spacer, the third spacer including a nitride; a fourth spacer on an upper portion of the outer sidewall of the second spacer and the third spacer; a fifth spacer and a sixth spacer sequentially stacked in a horizontal direction from an outer sidewall of the fourth spacer.

### CROSS-REFERENCE TO RELATED APPLICATION

This application claims priority under 35 U.S.C. § 119 to Korean Patent Application No. 10-2022-0166329, filed on Dec. 2, 2022, in the Korean Intellectual Property Office, the disclosure of which is hereby incorporated by reference in its entirety.

### 1. Field

Example embodiments relate to a semiconductor device. More particularly, example embodiments relate to dynamic random access memory (DRAM) devices.

### 2. DESCRIPTION OF THE RELATED ART

In a DRAM device, a bit line structure may have a first conductive pattern including polysilicon doped with impurities and a second conductive pattern including metal which are sequentially stacked. The bit line structure may be in contact with and electrically connected to an active pattern, and a spacer structure may be formed on a sidewall of the bit line structure.

### SUMMARY

According to example embodiments, there is provided a semiconductor device. The semiconductor device may include an active pattern on a substrate; a gate structure in an upper portion of the active pattern; a bit line structure on the active pattern; a lower spacer structure on a lower sidewall of the bit line structure; an upper spacer structure on the lower spacer structure, the upper spacer structure contacting an upper sidewall of the bit line structure; a contact plug structure on an upper portion of the active pattern adjacent to the bit line structure; and a capacitor on the contact plug structure. The lower spacer structure includes a first lower spacer, a second lower spacer and a third lower spacer sequentially stacked in a horizontal direction from the lower sidewall of the bit line structure, the horizontal direction being substantially parallel to an upper surface of the substrate, the first lower spacer includes an oxide of a first metal, the second lower spacer includes an oxide of a second metal that is different from the first metal, and the third lower spacer includes a nitride.

According to example embodiments, there is provided a semiconductor device. The semiconductor device may include an active pattern on a substrate; a gate structure in an upper portion of the active pattern; a bit line structure on the active pattern, the bit line structure including a first metal; a first spacer on a sidewall of the bit line structure, the first spacer including an oxide of a second metal that has an ionization energy smaller than that of the first metal; a second spacer on an outer sidewall of the first spacer, the second spacer including an oxide of a third metal that is different from the second metal; a third spacer on a lower portion of an outer sidewall of the second spacer, the third spacer including a nitride; a fourth spacer on an upper portion of the outer sidewall of the second spacer and the third spacer; a fifth spacer and a sixth spacer sequentially stacked in a horizontal direction from an outer sidewall of the fourth spacer, the horizontal direction being substantially parallel to an upper surface of the substrate; a contact plug structure on an upper portion of the active pattern adjacent to the bit line structure; and a capacitor on the contact plug structure.

According to example embodiments, there is provided a semiconductor device. The semiconductor device may include an active pattern on a substrate; a gate structure in an upper portion of the active pattern; a bit line structure on the active pattern, the bit line structure including a first conductive pattern, a second conductive pattern and a capping pattern sequentially stacked in a vertical direction substantially perpendicular to an upper surface of the substrate; a first lower spacer at least partially covering a sidewall of the first conductive pattern, the first lower spacer including silicon oxide; a second lower spacer at least partially covering an outer sidewall of the first lower spacer, the second lower spacer including an oxide of a first metal; a third lower spacer on an outer sidewall of the second lower spacer, the third lower spacer including a second metal that is different from the first metal; a fourth lower spacer on the third lower spacer, the fourth lower spacer including a nitride; an upper spacer structure contacting upper surfaces of the first to third lower spacers and an upper sidewall of the bit line structure; a contact plug structure on an upper portion of the active pattern adjacent to the bit line structure; and capacitor on the contact plug structure.

### BRIEF DESCRIPTION OF THE DRAWINGS

Features will become apparent to those of skill in the art by describing in detail exemplary embodiments with reference to the attached drawings, in which:

FIGS. 1 and 2 are a plan view and a cross-sectional view illustrating a semiconductor device in accordance with example embodiments.

FIGS. 3 to 21 are plan views and cross-sectional views illustrating stages in a method of manufacturing a semiconductor device according to example embodiments.

FIG. 22 is a cross-sectional view illustrating a semiconductor device in accordance with example embodiments.

FIGS. 23 and 24 are cross-sectional views illustrating stages in a method of manufacturing a semiconductor device according to example embodiments.

FIG. 25 is a cross-sectional view illustrating a semiconductor device in accordance with example embodiments.

FIG. 26 is a cross-sectional view illustrating a stage in a method of manufacturing a semiconductor device according to example embodiments.

FIG. 27 is a cross-sectional view illustrating a semiconductor device in accordance with example embodiments.

FIG. 28 is a cross-sectional view illustrating a stages in a method of manufacturing a semiconductor device according to example embodiments.

### DETAILED DESCRIPTION

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a substrate 100, which may be substantially orthogonal to each other, are referred to as first and second directions D1 and D2, respectively, and a direction among the horizontal directions, which may have an acute angle with respect to each of the first and second directions D1 and D2, is referred to as a third direction D3. Additionally, a direction substantially perpendicular to the upper surface of the substrate 100 is referred to as a vertical direction.

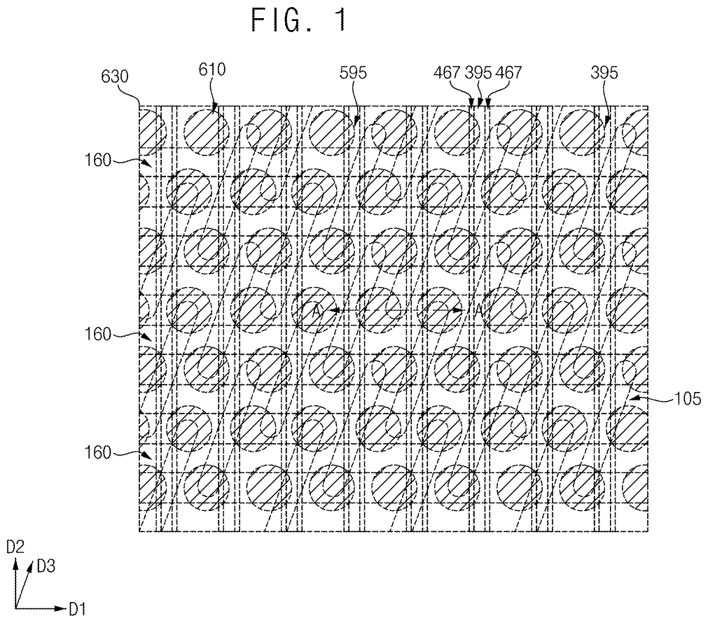

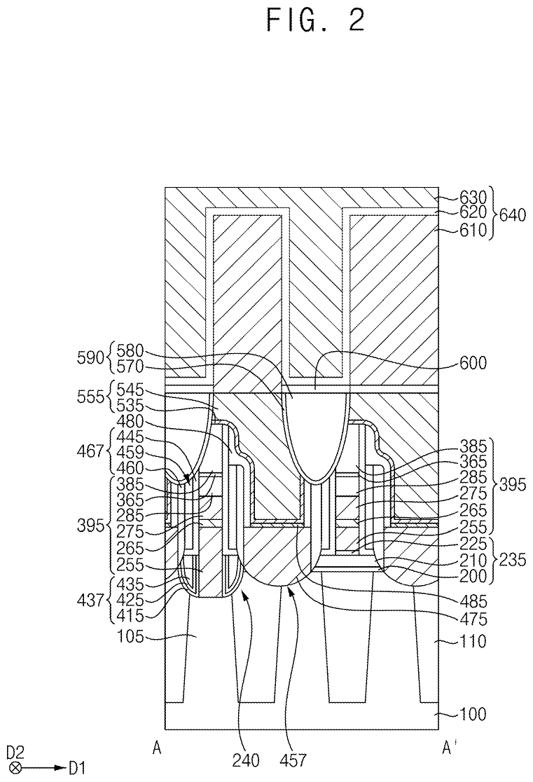

FIG. 1 is a plan view illustrating a semiconductor device in accordance with example embodiments, and FIG. 2 is a cross-sectional view along line A-A′ of FIG. 1.

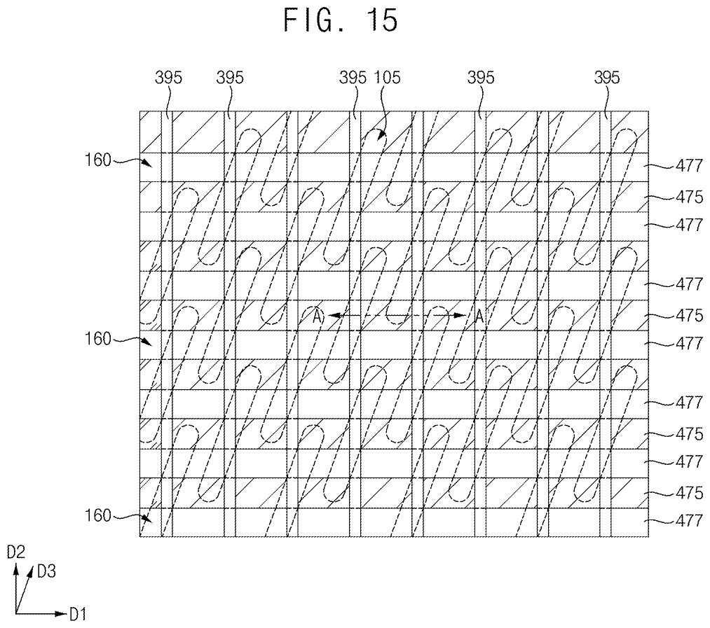

Referring to FIGS. 1 and 2, the semiconductor device may include an active pattern 105, an isolation pattern 110, a gate structure 160, a bit line structure 395, a lower spacer structure 437, an upper spacer structure 467, a seventh spacer 480, a contact plug structure, and a capacitor 640 on the substrate 100. The semiconductor device may further include a first insulation pattern structure 235, a first mask 285, first and second etch stop patterns 365 and 600, and first and second capping patterns 385 and 477 (FIG. 15).

The substrate 100 may include a semiconductor material, e.g., silicon, germanium, silicon-germanium, etc., or III-V semiconductor compounds, e.g., GaP, GaAs, GaSb, etc. In some embodiments, the substrate 100 may include a silicon-on-insulator (SOI) substrate or a germanium-on-insulator (GOI) substrate.

The active pattern 105 may extend (e.g., lengthwise) in the third direction D3, and a plurality of active patterns 105 may be spaced apart from each other in the first and second directions D1 and D2. A sidewall of the active pattern 105 may be covered by the isolation pattern 110. The active pattern 105 may include substantially the same material as the substrate 100, and the isolation pattern 110 may include an oxide, e.g., silicon oxide.

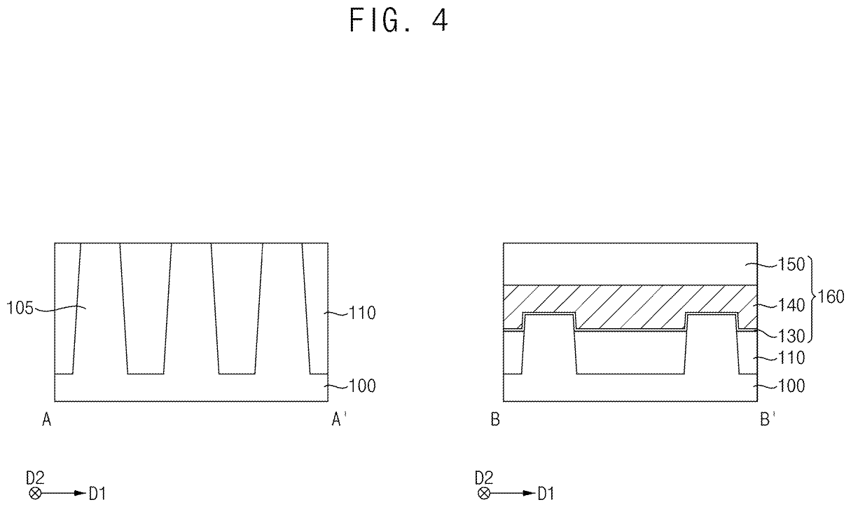

Referring to FIGS. 1 and 2 together with FIG. 4, the gate structure 160 may be formed in a second recess extending (e.g., lengthwise) in the first direction D1 through upper portions of the active pattern 105 and the isolation pattern 110. The gate structure 160 may include a gate insulation pattern 130 on a bottom and a sidewall of the second recess, a gate electrode 140 on a portion of the gate insulation pattern 130 on the bottom and a lower sidewall of the second recess, and a gate mask 150 on the gate electrode 140 and filling an upper portion of the second recess.

The gate insulation pattern 130 may include an oxide, e.g., silicon oxide, the gate electrode 140 may include, e.g., a metal, a metal nitride, a metal silicide, etc., and the gate mask 150 may include an insulating nitride, e.g., silicon nitride. In example embodiments, the gate structure 160 may extend (e.g., lengthwise) in the first direction D1, and a plurality of gate structures 160 may be spaced apart from each other in the second direction D2.

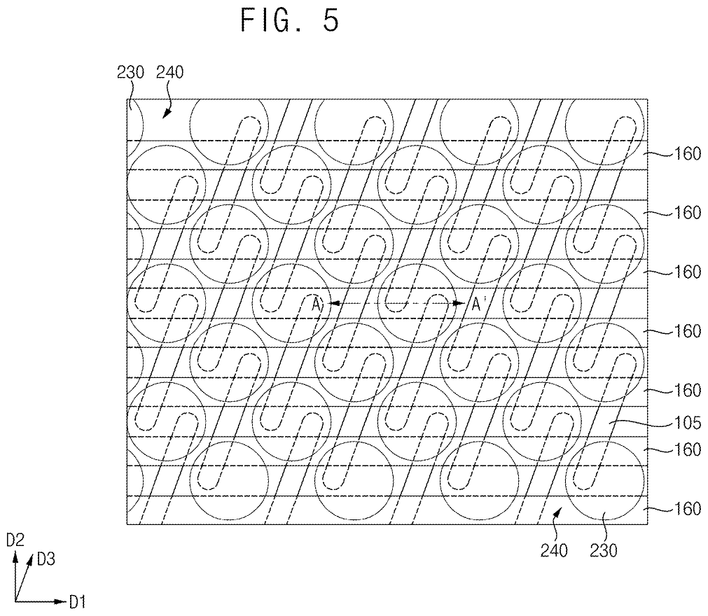

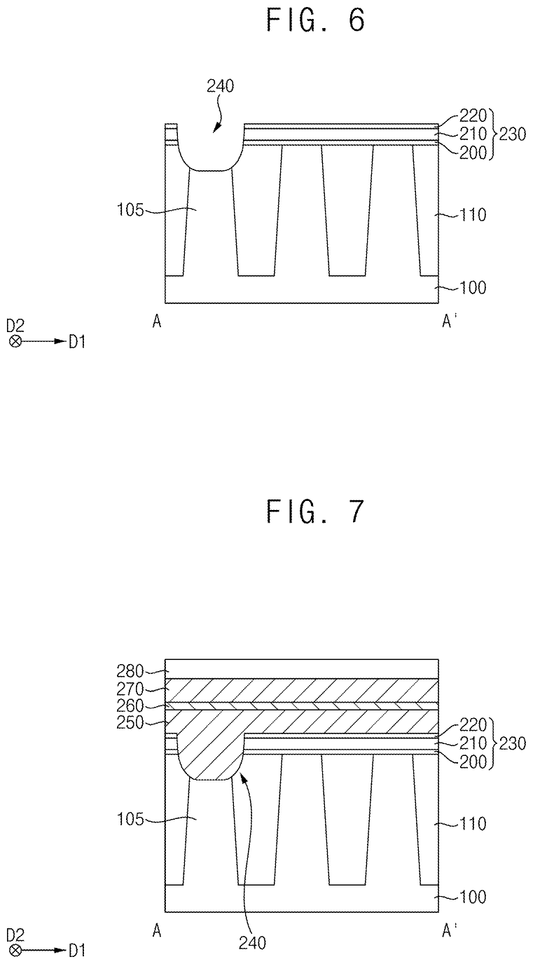

Referring to FIGS. 1 and 2 together with FIGS. 5 and 6, a first opening 240 extending through an insulating layer structure 230 and exposing upper surfaces of the active pattern 105, the isolation pattern 110, and the gate mask 150 of the gate structure 160 may be formed, and an upper surface of a central portion in the third direction D3 of the active pattern 105 may be exposed by the first opening 240.

In example embodiments, an area of a bottom of the first opening 240 may be greater than an area of the upper surface of the active pattern 105. Thus, the first opening 240 may also expose an upper surface of a portion of the isolation pattern 110 adjacent to the active pattern 105. Additionally, the first opening 240 may extend through upper portions of the active pattern 105 and the portion of the isolation pattern 110 adjacent thereto, and thus the bottom of the first opening 240 may be lower than an upper surface of each of opposite edge portions in the third direction D3 of the active pattern 105.

Referring to FIG. 2, the bit line structure 395 may include a first conductive pattern 255, a first barrier pattern 265, a second conductive pattern 275, a first mask 285, a first etch stop pattern 365, and a first capping pattern 385 sequentially stacked in the vertical direction in the first opening 240 or the first insulation pattern structure 235. The first conductive pattern 255, the first barrier pattern 265 and the second conductive pattern 275 may collectively form a conductive structure, and the first mask 285, the first etch stop pattern 365 and the first capping pattern 385 may collectively form an insulation structure.

The first conductive pattern 255 may include, e.g., doped polysilicon, the first barrier pattern 265 may include a metal nitride, e.g., titanium nitride, or a metal silicon nitride, e.g., titanium silicon nitride, the second conductive pattern 275 may include a first metal, e.g., tungsten, and each of the first mask 285, the first etch stop pattern 365, and the first capping pattern 385 may include an insulating nitride, e.g., silicon nitride. In example embodiments, the bit line structure 395 may extend (e.g., lengthwise) in the second direction D2 on the substrate 100, and a plurality of bit line structures 395 may be spaced apart from each other in the first direction D1.

The lower spacer structure 437 may be formed in the first opening 240, and may contact a lower sidewall of the bit line structure 395. The lower spacer structure 437 may include first to third spacers 415, 425 and 435 sequentially stacked in the horizontal direction. The second spacer 425 may cover a sidewall and a lower surface of the third spacer 435, and the first spacer 415 may cover a sidewall and a lower surface of the second spacer 425. For example, as illustrated in FIG. 2, a height of an upper surface of the lower spacer structure 437 may be lower than a height of an upper surface of the first conductive pattern 255, e.g., relative to a bottom of the substrate 100.

The first spacer 415 may include, e.g., an oxide of a second metal, the second spacer 425 may include, e.g., an oxide of a third metal, and the third spacer may include an insulating nitride, e.g., silicon nitride. In example embodiments, the second metal may include, e.g., aluminum (Al), and the third metal may include, e.g., zirconium (Zr) or hafnium (Hf). Accordingly, the first spacer 415 may include, e.g., aluminum oxide, and the second spacer 425 may include, e.g., zirconium oxide or hafnium oxide.

The first insulation pattern structure 235 may be formed on the active pattern 105 and the isolation pattern 110 under the bit line structure 395, and may include first, second and third insulation patterns 205, 215 and 225 sequentially stacked in the vertical direction (FIG. 13). The first and third insulation patterns 205 and 225 may include an oxide, e.g., silicon oxide, and the second insulation pattern 215 may include an insulating nitride, e.g., silicon nitride.

The contact plug structure may include a lower contact plug 475, a metal silicide pattern 485, and an upper contact plug 555 sequentially stacked in the vertical direction on the active pattern 105 and the isolation pattern 110.

The lower contact plug 475 may contact the upper surface of each of opposite edge portions in the third direction D3 of the active pattern 105. In example embodiments, a plurality of lower contact plugs 475 may be spaced apart from each other in the second direction D2, and a second capping pattern 477 may be formed between neighboring ones of the lower contact plugs 475 in the second direction D2 (FIG. 15). The second capping pattern 477 may include an insulating nitride, e.g., silicon nitride. The lower contact plug 475 may include, e.g., doped polysilicon, and the metal silicide pattern 485 may include, e.g., titanium silicide, cobalt silicide, nickel silicide, etc.

The upper contact plug 555 may include a second metal pattern 545 and a second barrier pattern 535 covering a lower surface of the second metal pattern 545. The second metal pattern 545 may include a metal, e.g., tungsten, and the second barrier pattern 535 may include a metal nitride, e.g., titanium nitride.

In example embodiments, a plurality of upper contact plugs 555 may be spaced apart from each other in the first and second directions D1 and D2, and may be arranged in a honeycomb pattern or a lattice pattern in a plan view (FIG. 19). Each of the upper contact plugs 555 may have a shape of, e.g., a circle, an ellipse, or a polygon in a plan view.

The upper spacer structure 467 may include a fourth spacer 445 covering an upper sidewall of the bit line structure 395 and a sidewall of the third insulation pattern 225, an air spacer 459 on a lower portion of an outer sidewall of the fourth spacer 445, and a sixth spacer 460 on an outer sidewall of the air spacer 459, a sidewall of the first insulation pattern structure 235, and a portion of an upper surface of the lower spacer structure 437.

In example embodiments, a cross-section in the first direction D1 of the fourth spacer 445 may have an “L” shape. Each of the fourth and sixth spacers 445 and 460 may include an insulating nitride, e.g., silicon nitride, and the air spacer 459 may include air.

The seventh spacer 480 may be formed on the outer sidewall of the fourth spacer 445 on the upper sidewall of the bit line structure 395, and may cover an upper end of the air spacer 459 and an upper surface of the sixth spacer 460. The seventh spacer 480 may include an insulating nitride, e.g., silicon nitride.

Referring to FIGS. 1 and 2 together with FIGS. 30 and 31, the second insulation pattern structure 590 may include a fourth insulation pattern 570 on an inner wall of a sixth opening 560, which may extend through the upper contact plug 555, a portion of the insulation structure of the bit line structure 395, and a portion of the upper spacer structure 467 and surround the upper contact plug 555 in a plan view, and a fifth insulation pattern 580 on the fourth insulation pattern 570 and filling a remaining portion of the sixth opening 560. The upper end of the air spacer 459 may be closed by the fourth insulation pattern 570. Each of the fourth and fifth insulation patterns 570 and 580 may include an insulating nitride, e.g., silicon nitride.

The second etch stop pattern 600 may be formed on the second insulation pattern structure 590. The second etch stop pattern 600 may include an insulating nitride, e.g., silicon boronitride.

The capacitor 640 may be disposed on the upper contact plug 555. The capacitor 640 may include a lower electrode 610 having a shape of a pillar or a cylinder, a dielectric layer 620 on a surface of the lower electrode 610, and an upper electrode 630 on the dielectric layer 620. Each of the lower electrode 610 and the upper electrode 630 may include, e.g., a metal, a metal nitride, a metal silicide, polysilicon doped with impurities, etc., and the dielectric layer 620 may include, e.g., a metal oxide.

In example embodiments, the lower spacer structure 437 may be formed on the sidewall of the bit line structure 395 having the first conductive pattern 255 including polysilicon doped with n-type impurities. The first spacer 415 of the lower spacer structure 437, which is in contact with the sidewall of the bit line structure 395, may include an oxide of the second metal, and the second spacer 425 in contact with the first spacer 415 may include an oxide of the third metal.

For example, if the first spacer 415 were to include an insulating nitride, e.g., silicon nitride, electrons of the first conductive pattern 255 would have been trapped inside the first spacer 415 to carry a negative charge, and accordingly, a depletion region would have been generated at each side of the first conductive pattern 255 contacting the first spacer 415. The depletion region could have interrupted current flow within the bit line structure 395, so as to reduce an effective diameter of the bit line structure 395.

However, if a physical diameter of the bit line structure 395 were to be enlarged in order to increase the effective diameter of the bit line structure 395, an electrical short could have occurred between adjacent ones of the lower contact plugs 475. Further, if conductivity of the first conductive pattern 255 were to be increased (by increasing a concentration of impurities included therein) in order to increase the effective diameter, during an etching process for forming the bit line structure 395, the first conductive pattern 255 could have been excessively etched, thereby breaking the first conductive pattern 255 or causing silicon diffusion from the first conductive pattern 255 toward the first barrier pattern 265 to form voids within the first conductive pattern 255.

In contrast, according to example embodiments, each of the first and second spacers 415 and 425 on the sidewall of the first conductive pattern 255 of the bit line structure 395 may include a material other than an insulating nitride. For example, the first and second spacers 415 and 425 may include aluminum oxide and hafnium oxide, respectively.

In detail, hafnium oxide contains hole traps, and thus the second spacer 425 (which is formed of hafnium oxide) may carry a positive charge. However, if the second spacer 245 were to directly contacts the sidewall of the first conductive pattern 255 containing silicon, a defect would have occurred at an interface between the first conductive pattern 255 and the second spacer 245, and a density of electron traps could have increased due to the defect. If the number of the electron traps were to exceed the number of the hole traps in the second spacer 425, the second spacer 425 would have carried a negative charge.

In contrast, according to example embodiments, the first spacer 415 including aluminum oxide may be disposed between the first conductive pattern 255 (which includes silicon) and the second spacer 425 (which includes hafnium oxide). Accordingly, as the first spacer 415 separates (e.g., completely separates) between the first conductive pattern 255 and the second spacer 425, a direct contact between the first conductive pattern 255 and the second spacer 24may be prevented, thereby reducing defects density of electron traps in the second spacer 425. Accordingly, the second spacer 425 may carry a positive charge. Additionally, as the first spacer 415 is disposed between the first conductive pattern 255 and the second spacer 425, diffusion of hafnium may also be prevented or substantially minimized.

Furthermore, the first spacer 415 itself containing aluminum oxide may include hole traps, and thus the first spacer 415 may carry a positive charge as the second spacer 425. Accordingly, each of the first and second spacers 415 and 425 on the sidewall of the first conductive pattern 255 may carry a positive charge, and thus, the effective diameter of the bit line structure 395 may increase.

As a result, current may flow smoothly within the bit line structure 395 without increasing the diameter of the bit line structure 395 or increasing the concentration of n-type impurities included in the first conductive pattern 255. Thus, the semiconductor device may have improved electrical characteristics.

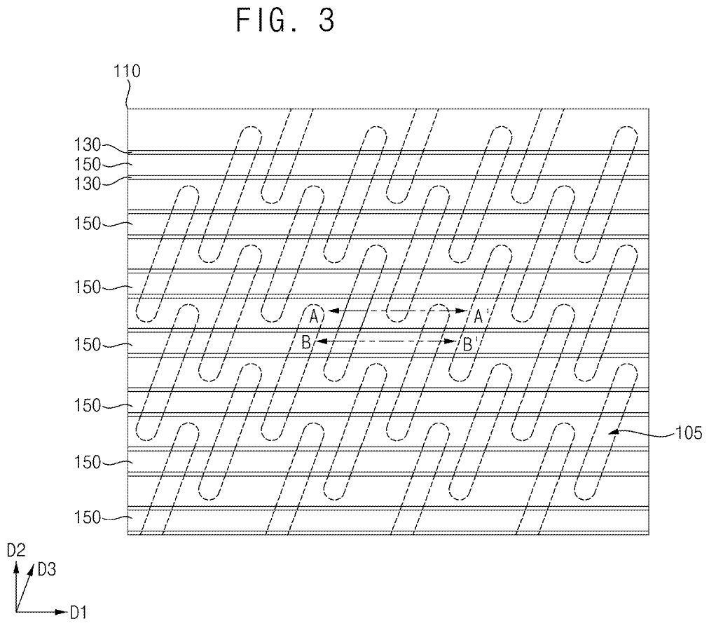

FIGS. 3 to 21 are plan views and cross-sectional views of stages in a method of manufacturing a semiconductor device according to example embodiments. Specifically, FIGS. 3, 5, 8, 15 and 19 are plan views, FIG. 4 includes cross-sectional views along lines A-A′ and B-B′ of FIG. 3, respectively, and FIGS. 6-7, 9-14, 16-18 and 20-21 are cross-sectional views along line A-A′, respectively, of corresponding plan views.

Referring to FIGS. 3 and 4, an upper portion of the substrate 100 may be removed to form a first recess, and the isolation pattern 110 may be formed in the first recess. As the isolation pattern 110 is formed on the substrate 100, the active pattern 105 of which a sidewall is covered by the isolation pattern 110 may be defined.

The active pattern 105 and the isolation pattern 110 on the substrate 100 may be partially etched to form a second recess extending in the first direction D1, and the gate structure 160 may be formed in the second recess. In example embodiments, the gate structure 160 may extend in the first direction D1, and a plurality of gate structures 160 may be spaced apart from each other in the second direction D2.

Referring to FIGS. 5 and 6, the insulating layer structure 230 may be formed on the active pattern 105, the isolation pattern 110, and the gate structure 160. The insulating layer structure 230 may include first to third insulating layers 200, 210, and 220 sequentially stacked.

The insulating layer structure 230 may be patterned, and the active pattern 105, the isolation pattern 110, and the gate mask 150 included in the gate structure 160 may be partially etched using the patterned insulating layer structure 230 as an etching mask to form the first opening 240. In example embodiments, the insulating layer structure 230 may have a circular shape or an elliptical shape in a plain view, and a plurality of insulating layer structures 230 may be spaced apart from each other in the first and second directions D1 and D2. Each of the insulating layer structures 230 may overlap end portions of ones of the active patterns 105 neighboring in the third direction D3, which may face each other, in a vertical direction substantially orthogonal to the upper surface of the substrate 100.

Referring to FIG. 7, a first conductive layer 250, a first barrier layer 260, a second conductive layer 270, and a first mask layer 280 may be sequentially stacked on the insulating layer structure 230, and the active pattern 105, the isolation pattern 110 and the gate structure 160 exposed by the first opening 240. The first conductive layer 250 may fill the first opening 240.

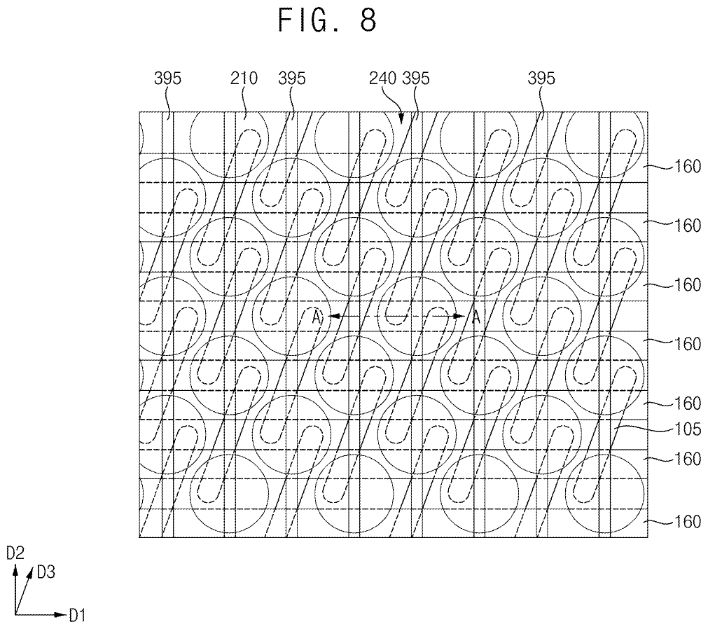

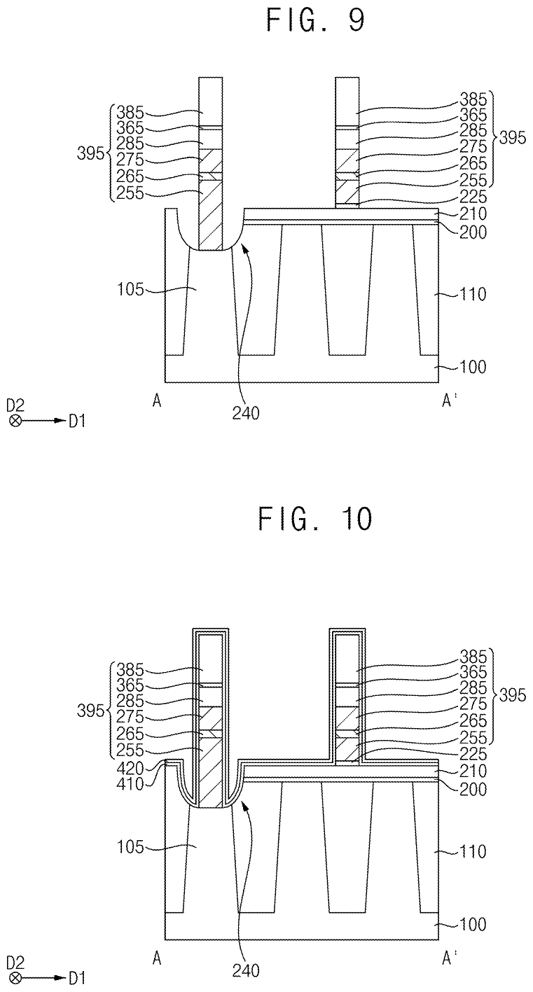

Referring to FIGS. 8 and 9, a first etch stop layer and a first capping layer may be sequentially formed on the conductive structure layer, the first capping layer may be etched to form the first capping pattern 385, and the first etch stop layer, the first mask layer 280, the second conductive layer 270, the first barrier layer 260 and the first conductive layer 250 may be sequentially etched using the first capping pattern 385 as an etch mask. In example embodiments, the first capping pattern 385 may extend in the second direction D2, and a plurality of first capping patterns 385 may be spaced apart from each other in the first direction D1.

By the etching process, the first conductive pattern 255, the first barrier pattern 265, the second conductive pattern 275, the first mask 285, the first etch stop pattern 365 and the first capping pattern 385 may be sequentially stacked on the first opening 240, and the third insulation pattern 225, the first conductive pattern 255, the first barrier pattern 265, the second conductive pattern 275, the first mask 285, the first etch stop pattern 365, and the first capping pattern 385 may be sequentially stacked on the second insulating layer 210 of the insulating layer structure 230 at an outside of the first opening 240.

Hereinafter, the first conductive pattern 255, the first barrier pattern 265, the second conductive pattern 275, the first mask 285, the first etch stop pattern 365, and the first capping pattern 385 sequentially stacked may be collectively referred to as the bit line structure 395. The first conductive pattern 255, the first barrier pattern 265, and the second conductive pattern 275 may collectively form a conductive structure, and the first mask 285, the first etch stop pattern 365, and the first capping pattern 385 may collectively form an insulating structure. In example embodiments, the bit line structure 395 may extend in the second direction D2, and a plurality of bit line structures 395 may be spaced apart from each other in the first direction D1.

Referring to FIG. 10, a first spacer layer 410 and a second spacer layer 420 may be sequentially formed on the substrate 100. In example embodiments, each of the first and second spacer layers 410 and 420 may be formed by a deposition process, e.g., an atomic layer deposition (ALD) process or a chemical vapor deposition (CVD) process. In example embodiments, the first spacer layer 410 may include an oxide of a second metal, and the second spacer layer 420 may include an oxide of a third metal. For example, the second and third metals may be different from each other, e.g., the first and second spacer layers 410 and 420 may include aluminum oxide and hafnium oxide, respectively.

Referring to FIG. 11, a third spacer layer 430 may be formed on the first and second spacer layers 410 and 420. The third spacer layer 430 may fill a remaining portion of the first opening 240. In example embodiments, the third spacer layer 430 may be formed through a deposition process, e.g., an atomic layer deposition (ALD) process or a chemical vapor deposition (CVD) process. The third spacer layer may include a nitride, e.g., silicon nitride.

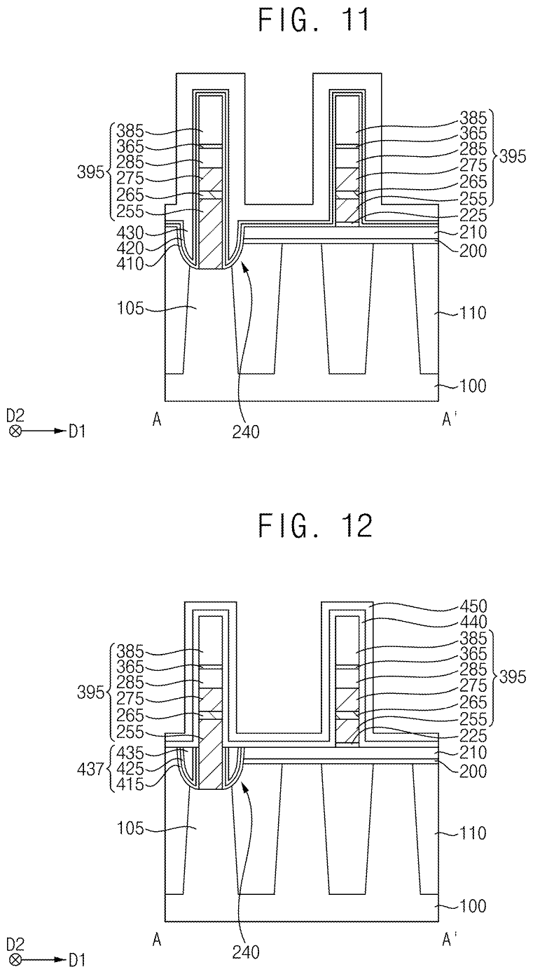

Referring to FIG. 12, an etching process may be performed on the first to third spacer layers 410, 420 and 430. In example embodiments, the etching process may be a wet etching process using, e.g., phosphoric acid (H₂PO₃), SC1, and hydrofluoric acid (HF) as an etchant, and portions of the first to third spacer layers 410, 420 and 430, except for portions thereof in the first opening 240, may be removed. Accordingly, most portion of a surface of the bit line structure 395, i.e., an entire portion of the surface of the bit line structure 395 except for a portion of the surface thereof in the first opening 240, may be exposed, and the first to third spacer layers 410, 420 and 430 remaining in the first opening 240 may form the first to third spacers 415, 425 and 435, respectively. For example, referring to FIGS. 11-12, the first to third spacer layers 410, 420 and 430 may be etched until an upper surface of the second insulating layer 210 is exposed and is coplanar with upper surfaces of the resultant first to third spacers 415, 425 and 435. The first to third spacers 415, 425 and 435 may collectively form the lower spacer structure 437. A fourth spacer layer 440 and a fifth spacer layer 450 may be, e.g., conformally, formed on the exposed surface of the bit line structure 395, upper surfaces of the first to third spacers 415, 425 and 435 and an upper surface of the second insulating layer 210.

Referring to FIG. 13, the fourth and fifth spacer layers 440 and 450 may be anisotropically etched to form the fourth and fifth spacers 445 and 455, respectively, on the sidewall of the bit line structure 395, a sidewall of the third insulation pattern 325, and the upper surfaces of the first to third spacers 415, 425 and 435. A dry etching process may be performed using the first capping pattern 385 and the fourth and fifth spacers 445 and 455 as an etch mask to partially remove the first and second insulating layers 200 and 210. In addition, an upper portion of the active pattern 105, and an upper portion of the isolation pattern 110 and an upper portion of the gate mask 150 adjacent thereto may be partially removed to form a second opening 457 by the drying process.

By the dry etching process, the first and second insulating layers 200 and 210 may be partially removed to remain as the first and second insulation patterns 205 and 215, respectively, under the bit line structure 395. The first to third insulation patterns 205, 215 and 225 sequentially stacked under the bit line structure 395 may collectively form the first insulation pattern structure 235.

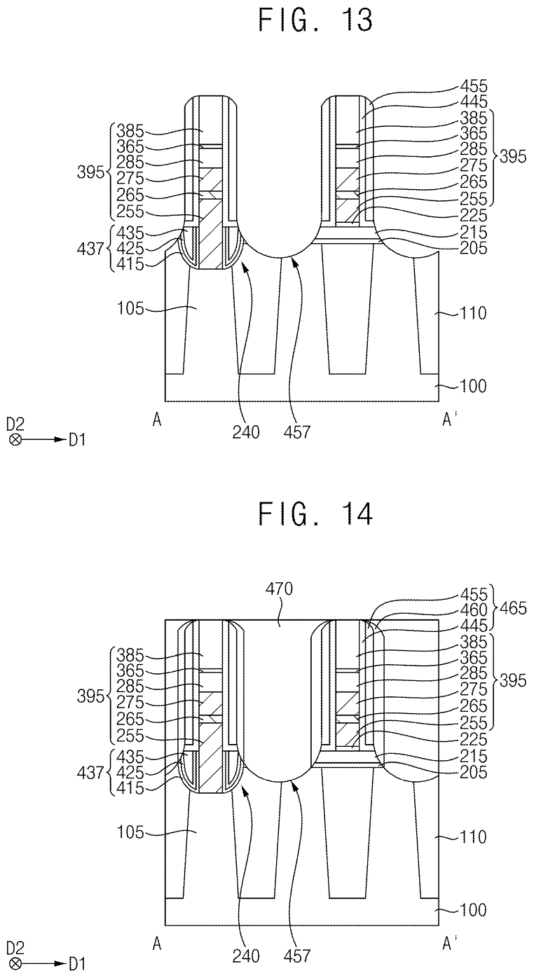

Referring to FIG. 14, a sixth spacer layer may be formed on an upper surface of the first capping pattern 385, an upper surface of the fourth spacer 445, an upper surface and an outer sidewall of the fifth spacer 455, a portion of the upper surface of the lower spacer structure 437, and the active pattern 105, the isolation pattern 110, and the gate mask 150 exposed by the second opening 457. The sixth spacer layer may be anisotropically etched to form the sixth spacer 455 on the outer sidewall of the fifth spacer 455 and the portion of the upper surface of the lower spacer structure 437. The fourth to sixth spacers 445, 455 and 460 sequentially stacked on the sidewall of the bit line structure 395 in the horizontal direction may be collectively referred to as a preliminary upper spacer structure 465.

A sacrificial layer may be formed to fill the second opening 457 on the substrate 100 to a sufficient height, and an upper portion of the first sacrificial layer may be planarized until the upper surface of the first capping pattern 385 is exposed to form a sacrificial pattern 470 in the second opening 457. In example embodiments, the sacrificial pattern 470 may extend in the second direction D2, and a plurality of sacrificial patterns 470 may be spaced apart from each other in the first direction D1 by the bit line structures 395. For example, the sacrificial pattern 470 may include an oxide, e.g., silicon oxide.

Referring to FIGS. 15 and 16, a second mask including a plurality of third openings, each of which may extend in the first direction D1, spaced apart from each other in the second direction D2 may be formed on the first capping pattern 385, the sacrificial pattern 470 and the preliminary upper spacer structure 465, and may be etched using the second mask as an etching mask.

In example embodiments, each of the third openings may overlap the gate structures 160 in the vertical direction. By the etching process, a fourth opening exposing upper surfaces of the active pattern 105 and the isolation pattern 110 may be formed between the bit line structures 395 on the substrate 100, and the sacrificial pattern 470 may be divided into a plurality of pieces spaced apart from each other in the second direction D2.

The second mask may be removed, and a second capping pattern 477 may be formed to fill the fourth opening. The sacrificial pattern 470 may be removed to form a fifth opening exposing upper surfaces of the active pattern 105 and the isolation pattern 110 adjacent thereto, a lower contact plug layer may be formed to fill the fifth opening on the first and second capping patterns 385 and 477, the sacrificial pattern 470 and the preliminary upper spacer structure 465, and an upper portion of the lower contact plug layer may be planarized until the upper surface of the first capping pattern 385 and upper surfaces of the sacrificial pattern 470 and the preliminary upper spacer structure 465 are exposed. Accordingly, the lower contact plug layer may be divided into a plurality of lower contact plugs 475 spaced apart from each other in the second direction D2 by the second capping pattern 477 between the bit line structures 395.

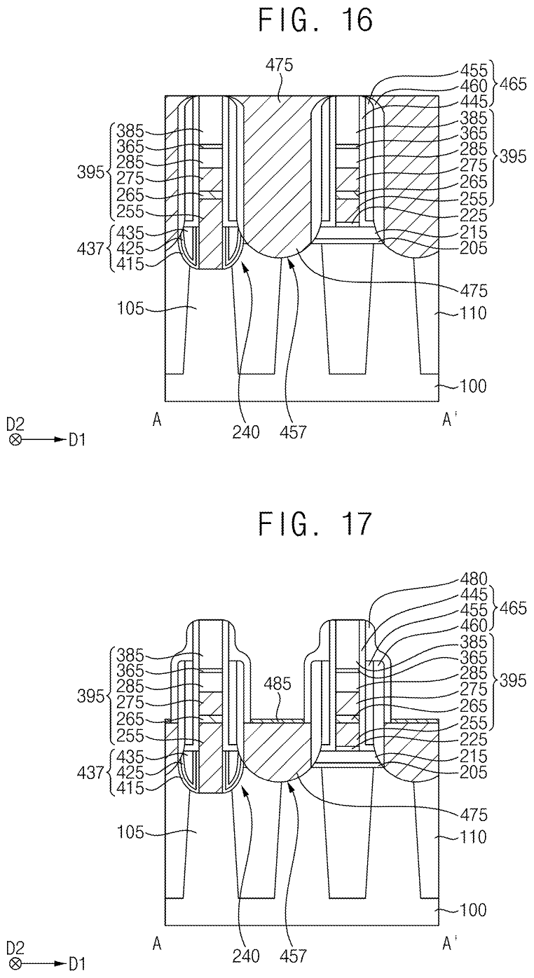

Referring to FIG. 17 an upper portion of the lower contact plug 475 may be removed to expose an upper portion of the preliminary upper spacer structure 465 on the sidewall of the bit line structure 395, and upper portions of the fifth and sixth spacers 455 and 460 of the exposed preliminary upper spacer structure 465 may be removed. An upper portion of the lower contact plug 475 may be additionally removed. Thus, an upper surface of the lower contact plug 475 may be lower than upper surfaces of the fifth and sixth spacers 455 and 460, e.g., relative to a bottom of the substrate 100.

A seventh spacer layer may be formed on the bit line structure 395, the preliminary upper spacer structure 465, the second capping pattern 477, and the lower contact plug 475, and may be anisotropically etched to form the seventh spacer 480 covering an upper portion of the preliminary upper spacer structure 465 on the sidewall in the first direction D1 of the bit line structure 395, and the upper surface of the lower contact plug 475 may be exposed by the etching process.

A metal silicide pattern 485 may be formed on the exposed upper surface of the lower contact plug 475. In example embodiments, the metal silicide pattern 485 may be formed by forming a first metal layer on the first and second capping patterns 385 and 477, the seventh spacer 480 and the lower contact plug 475, performing a heat treatment thereon, and removing an unreacted portion of the first metal layer.

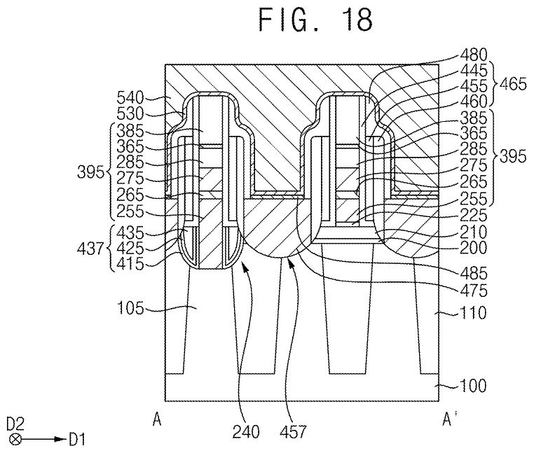

Referring to FIG. 18, a second barrier layer 530 may be formed on the first and second capping patterns 385 and 477, the seventh spacer 480, the metal silicide pattern 485, and the lower contact plug 475, and a second metal layer 540 may be formed on the second barrier layer 530 to fill a space between the bit line structures 395.

A planarization process may be performed on an upper portion of the second metal layer 540. The planarization process may include, e.g., a chemical mechanical polishing (CMP) process and/or an etch-back process.

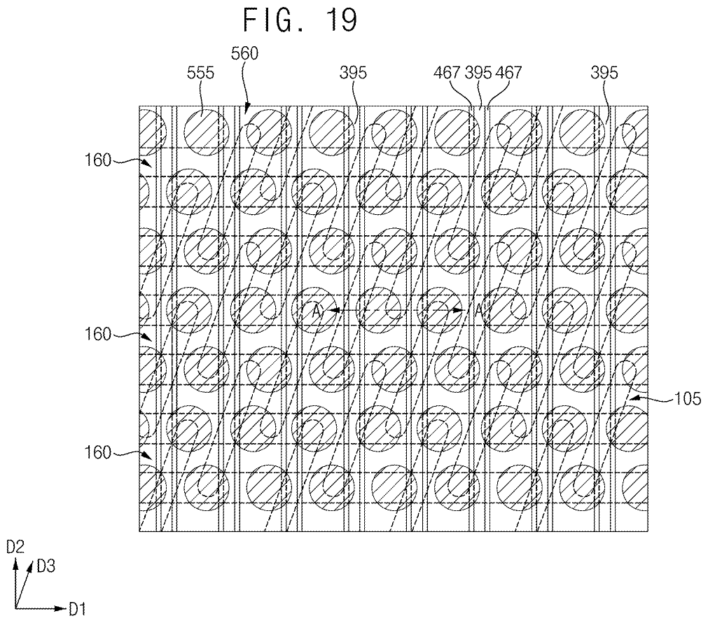

Referring to FIGS. 19 and 20, the second metal layer 540 and the second barrier layer 530 may be patterned to form the upper contact plug 555. In example embodiments, a plurality of upper contact plugs 555 may be formed, and a sixth opening 560 may be formed between the upper contact plugs 555.

The sixth opening 560 may be formed by partially removing the first and second capping patterns 385 and 477, the preliminary upper spacer structure 465 and the seventh spacer 480 as well as the second metal layer 540 and the second barrier layer 530. The lower contact plug 475, the metal silicide pattern 485 and the upper contact plug 555 sequentially stacked on the substrate 100 may collectively form the contact plug structure.

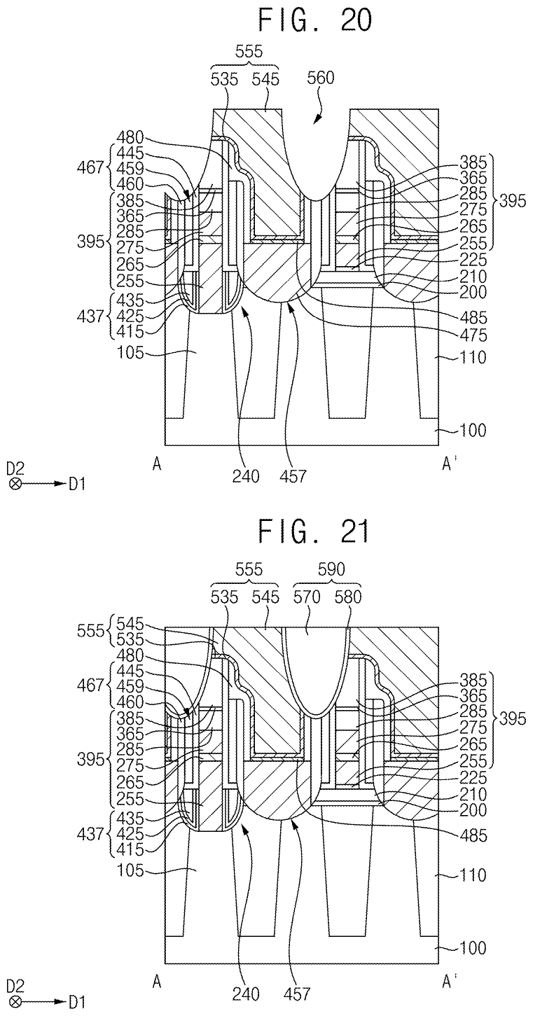

Referring to FIG. 21, the fifth spacer 455 included in the preliminary upper spacer structure 465 exposed by the sixth opening 560 may be removed to form an air gap, a fourth insulation pattern 570 may be formed on a bottom and a sidewall of the sixth opening 560, and a fifth insulation pattern 580 may be formed to fill a remaining portion of the sixth opening 560. The fourth and fifth insulation patterns 570 and 580 may collectively form the second insulation pattern structure 590.

A top end of the air gap may be covered by the fourth insulation pattern 570, and thus the air spacer 459 may be formed. The fourth spacer 445, the air spacer 459, and the sixth spacer 460 may collectively form the upper spacer structure 467.

Referring to FIGS. 1 and 2 again, the capacitor 640 may be formed to contact an upper surface of the upper contact plug 555. That is, the second etch stop pattern 600 and a mold layer may be sequentially formed on the upper contact plug 555 and the fourth and fifth insulation patterns 570 and 580, a seventh opening may be formed by partially etching the second etch stop pattern 600 and the mold layer to expose the upper surface of the upper contact plug 555. As the upper contact plugs 555 are arranged, e.g., in a honeycomb pattern in the first and second directions D1 and D2, in a plan view, the seventh opening may also be arranged, e.g., in a honeycomb pattern in the first and second directions D1 and D2, in a plan view.

The lower electrode 610 may be formed in the seventh opening to have a shape of, e.g., a pillar. The mold layer may be removed, and the dielectric layer 620 and the upper electrode 630 may be sequentially formed on the lower electrode 610 and the second etch stop pattern 600. Accordingly, the capacitor 640 including the lower electrode 610, the dielectric layer 620, and the upper electrode 630 that are sequentially stacked may be formed. In some embodiments, the lower electrode 610 may have a shape of a cylinder in the seventh opening.

Upper wirings may be further formed on the capacitor 640, and the manufacturing of the semiconductor device may be completed.

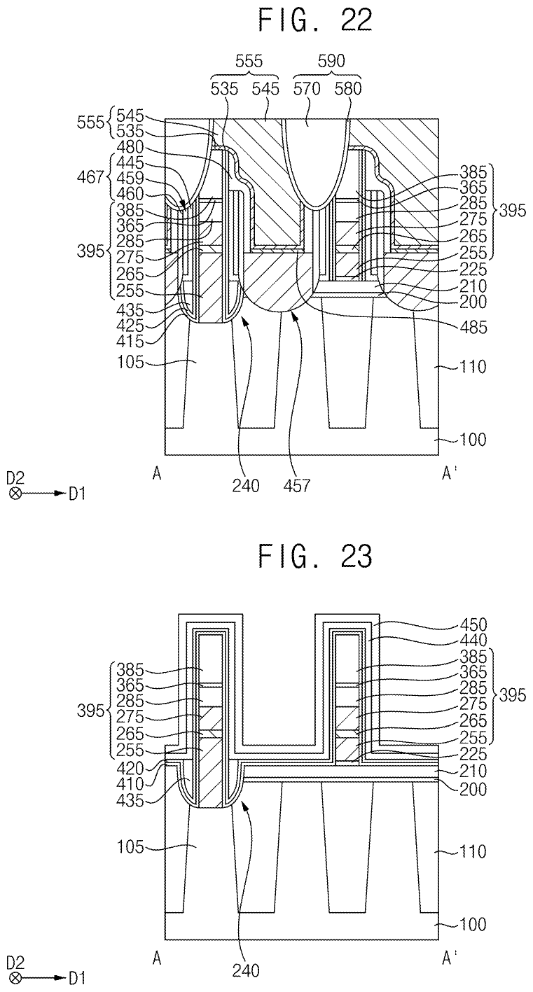

FIG. 22 is a cross-sectional view illustrating a semiconductor device in accordance with example embodiments. This semiconductor device in FIG. 22 may be substantially the same as or similar to the semiconductor device of FIGS. 1 and 2, and thus repeated explanations are omitted herein.

Referring to FIG. 22, the semiconductor device may include, instead of the upper and lower spacer structures 437 and 467, the first spacer 415 on the sidewall of the bit line structure 395, the second spacer 425 on the outer sidewall of the first spacer 415, the third spacer 435 on a lower portion of an outer sidewall of the second spacer 425, the fourth spacer 445 on the third spacer 435 and covering an upper portion of the outer sidewall of the second spacer 425, the air spacer 459 on a lower portion of an outer sidewall of the fourth spacer 445, the sixth spacer 460 on an outer sidewall of the air spacer 459, and the seventh spacer 480 in contact with an upper portion of the outer sidewall of the fourth spacer 445, an upper surface of the air spacer 459, and an upper surface and an upper portion of an outer sidewall of the sixth spacer 460.

In example embodiments, the second conductive pattern 275 of the bit line structure 395 may include the first metal, e.g., tungsten, and the first spacer 415 in contact with the second conductive pattern 275 may include a fourth metal having a smaller ionization energy than that of the first metal. In example embodiments, the fourth metal may include, e.g., titanium, aluminum, hafnium, zirconium, etc.

As the first spacer 415 includes the fourth metal having a smaller ionization energy than that of the first metal included in the second conductive pattern 275, the first spacer 415 may serve as an oxygen scavenger, which may prevent the second conductive pattern 275 from being oxidized.

FIGS. 23 to 24 are cross-sectional views illustrating a method of manufacturing a semiconductor device in accordance with example embodiments, and correspond to FIGS. 12 and 13, respectively. This method may include processes substantially the same as or similar to those illustrated with reference to FIGS. 3 to 21 and FIGS. 1 to 2, and thus repeated explanations thereof are omitted herein.

First, processes substantially the same as or similar to those described with reference to FIGS. 2 to 11 may be performed.

Referring to FIG. 23, unlike the processes illustrated with reference to FIG. 12, the etching process may be only performed on the third spacer layer 430, and not on the first and second spacer layers 410 and 420. Accordingly, the third spacer layer 430 may be transformed into the third spacer 435, and the third spacer 435 may be formed on the second spacer layer 420 within the first opening 240.

Referring to FIG. 24, unlike the processes illustrated with reference to FIG. 13, the first and second spacer layers 410 and 420 may be anisotropically etched along with the fourth and fifth spacer layers 440 and 450 to form first, second, fourth and fifth spacer 415, 425, 445 and 455, respectively, on the sidewall of the bit line structure. Manufacturing of the semiconductor device may be completed by performing processes that are substantially the same as or similar to those illustrated with reference to FIGS. 14 to 21 and FIGS. 1 and 2.

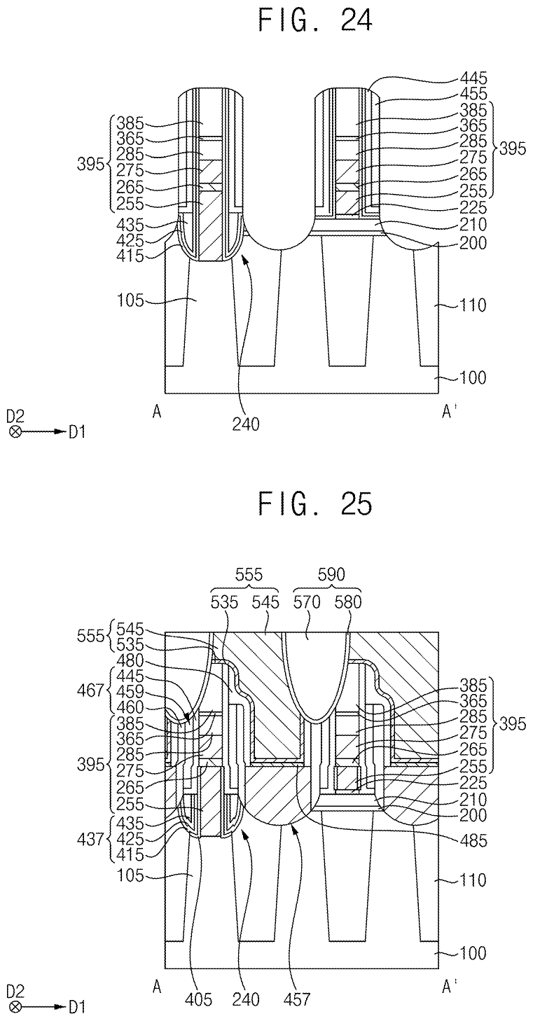

FIG. 25 is a cross-sectional view illustrating a semiconductor device in accordance with example embodiments. This semiconductor device may be substantially the same as or similar to the semiconductor device of FIGS. 1 and 2, except for further including an eighth spacer 405, and thus repeated explanations are omitted herein.

Referring to FIG. 25, the eighth spacer 405 may be formed to cover the sidewall of the first conductive pattern 255. Accordingly, the lower spacer structure 437 may contact a lower portion of an outer sidewall of the eighth spacer 405, and the upper spacer structure 467 may contact an upper portion of the outer sidewall wall of the eighth spacer 405.

The eighth spacer 405 may be formed not only on the sidewall of the first conductive pattern 255 but also on an edge of an upper portion of the active pattern 105 in the first opening 240 that is adjacent to the first conductive pattern 255. In example embodiments, the eighth spacer 405 may include silicon oxide or silicon oxide doped with impurities.

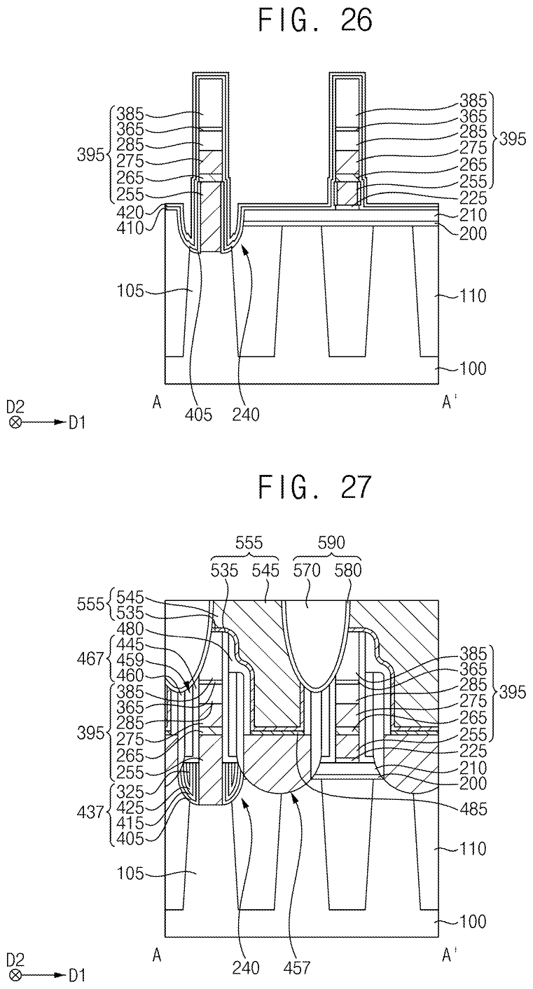

FIG. 26 is a cross-sectional view illustrating a method of manufacturing a semiconductor device in accordance with example embodiments, and corresponds to FIG. 10. This method may include processes substantially the same as or similar to those illustrated with reference to FIGS. 3 to 21 and FIGS. 1 to 2, and thus repeated explanations thereof are omitted herein.

First, processes substantially the same as or similar to those described with reference to FIGS. 2 to 9 may be performed.

Referring to FIG. 26, unlike the processes illustrated with reference to FIG. 10, a heat treatment process may be performed on the sidewall of the bit line structure 395 before forming the first and second spacer layers 410 and 420. Accordingly, the eighth spacer 405 including silicon oxide doped with n-type impurities may be formed on the sidewall in the first direction D1 of the first conductive pattern 255 that includes polysilicon doped with n-type impurities. The eighth spacer 405 may also be formed on a portion of the upper surface of the active pattern 105 that includes silicon.

Manufacturing of the semiconductor device may be completed by performing processes that are substantially the same as or similar to those illustrated with reference to FIGS. 11 to 21 and FIGS. 1 and 2.

FIG. 27 is a cross-sectional view illustrating a semiconductor device in accordance with example embodiments. This semiconductor device may be substantially the same as or similar to the semiconductor device of FIG. 25, except for the location of the eighth spacer 405, and thus repeated explanations are omitted herein.

Referring to FIG. 27, the eighth spacer 405 may cover the sidewall of the first conductive pattern 255 and the bottom of the first opening 240. Accordingly, the lower spacer structure 437 may not contact the lower sidewall of the bit line structure 395. In example embodiments, the eighth spacer 405 may cover the lower sidewall of the first conductive pattern 255 and a lower surface of the first spacer 415.

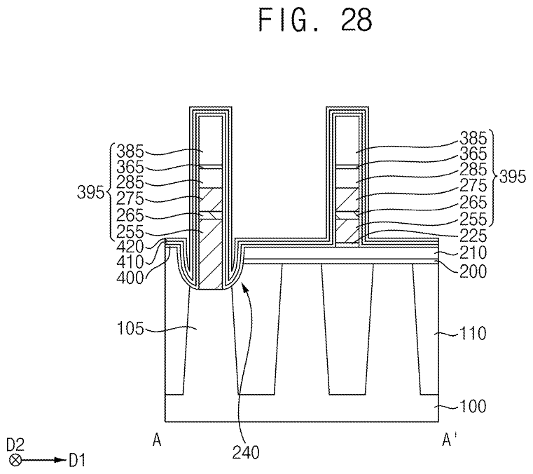

FIG. 28 is a cross-sectional view illustrating a method of manufacturing a semiconductor device in accordance with example embodiments, and corresponds to FIG. 10. This method may include processes substantially the same as or similar to those illustrated with reference to FIGS. 3 to 21 and FIGS. 1 to 2, and thus repeated explanations thereof are omitted herein.

First, processes substantially the same as or similar to those described with reference to FIGS. 2 to 9 may be performed.

Referring to FIG. 28, unlike the processes illustrated with reference to FIG. 10, an eighth spacer layer 400 may be formed by performing a deposition process on the substrate 100 on which the bit line structure 395 is formed. Accordingly, the eighth spacer layer 400 and the first and second spacer layers 410 and 420 may be sequentially stacked on the sidewall of the bit line structure 395.

Manufacturing of the semiconductor device may be completed by performing processes that are substantially the same as or similar to those illustrated with reference to FIGS. 11 to 21 and FIGS. 1 and 2. In example embodiments, the eighth spacer 405 may be naturally formed on the sidewall of the bit line structure 395 without performing a separate heat treatment process or deposition process.

By way of summation and review, as the DRAM device becomes highly integrated, the bit line structure may have reduced width, thereby reducing stability of the electric current flow therethrough. However, if the width of the bit line structure is increased to improve the electric current flow therethrough, an electrical short may occur between neighboring ones of the bit line structures.

In contrast, example embodiments provide a semiconductor having improved characteristics. That is, in example embodiments, current flow within the bit line structure may be smooth, and accordingly, the semiconductor device including the bit line structure may have improved electrical characteristics. In addition, a necking phenomenon in which a conductive pattern included in the bit line structure and including polysilicon doped with impurities is excessively etched to be broken may be prevented. Furthermore, voids may not be formed within the conductive pattern.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
an active pattern on the substrate;
a gate structure in an upper portion of the active pattern;
a bit line structure on the active pattern;
a lower spacer structure on a lower sidewall of the bit line structure;
an upper spacer structure on the lower spacer structure, the upper spacer structure contacting an upper sidewall of the bit line structure;
a contact plug structure on the upper portion of the active pattern, the contact plug structure being adjacent to the bit line structure; and
a capacitor on the contact plug structure,
wherein the lower spacer structure includes a first lower spacer, a second lower spacer, and a third lower spacer sequentially stacked in a horizontal direction from the lower sidewall of the bit line structure, the horizontal direction being substantially parallel to an upper surface of the substrate, and
wherein the first lower spacer includes an oxide of a first metal, the second lower spacer includes an oxide of a second metal that is different from the first metal, and the third lower spacer includes a nitride.

2. The semiconductor device as claimed in claim 1, wherein the first lower spacer is in contact with the lower sidewall of the bit line structure.

3. The semiconductor device as claimed in claim 1, wherein the first metal includes aluminum.

4. The semiconductor device as claimed in claim 1, wherein the second metal includes zirconium or hafnium.

5. The semiconductor device as claimed in claim 1, wherein the second lower spacer covers a sidewall and a lower surface of the third lower spacer, and the first lower spacer covers a sidewall and a lower surface of the second lower spacer.

6. The semiconductor device as claimed in claim 1, wherein:
the bit line structure includes a first conductive pattern, a barrier pattern, a second conductive pattern, and a capping pattern sequentially stacked in a vertical direction substantially perpendicular to the upper surface of the substrate, and
the first conductive pattern includes polysilicon doped with n-type impurities.

7. The semiconductor device as claimed in claim 6, wherein a height of an upper surface of the lower spacer structure is lower than a height of an upper surface of the first conductive pattern.

8. The semiconductor device as claimed in claim 6, further comprising a fourth lower spacer that covers a sidewall of the first conductive pattern and includes silicon oxide, the first lower spacer contacting a lower portion of an outer sidewall of the fourth lower spacer, and the upper spacer structure contacting an upper portion of the outer sidewall of the fourth lower spacer.

9. The semiconductor device as claimed in claim 6, further comprising a fourth lower spacer that covers a lower sidewall of the first conductive pattern and a sidewall and a lower surface of the first lower spacer, the fourth lower spacer including silicon oxide.

10. The semiconductor device as claimed in claim 1, wherein:
the upper spacer structure includes a first upper spacer, a second upper spacer, and a third upper spacer sequentially stacked in the horizontal direction from the upper sidewall of the bit line structure, and
each of the first and third upper spacers includes a nitride, and the second upper spacer includes air.

11. The semiconductor device as claimed in claim 10, wherein a cross-section in a direction of the first upper spacer has an “L” shape.

12. A semiconductor device, comprising:
a substrate;
an active pattern on the substrate;
a gate structure in an upper portion of the active pattern;
a bit line structure on the active pattern, the bit line structure including a first metal;
a first spacer on a sidewall of the bit line structure, the first spacer including an oxide of a second metal that has an ionization energy smaller than that of the first metal;
a second spacer on an outer sidewall of the first spacer, the second spacer including an oxide of a third metal that is different from the second metal;
a third spacer on a lower portion of an outer sidewall of the second spacer, the third spacer including a nitride;
a fourth spacer on an upper portion of the outer sidewall of the second spacer and the third spacer;
a fifth spacer and a sixth spacer sequentially stacked in a horizontal direction from an outer sidewall of the fourth spacer, the horizontal direction being substantially parallel to an upper surface of the substrate;
a contact plug structure on the upper portion of the active pattern and adjacent to the bit line structure; and
a capacitor on the contact plug structure.

13. The semiconductor device as claimed in claim 12, wherein the first metal includes tungsten.

14. The semiconductor device as claimed in claim 12, wherein the second metal includes at least one of titanium, aluminum, zirconium, and hafnium.

15. The semiconductor device as claimed in claim 12, wherein the third metal includes at least one of aluminum, zirconium, and hafnium.

16. The semiconductor device as claimed in claim 12, wherein the second metal includes aluminum, and the third metal includes hafnium or zirconium.

17. The semiconductor device as claimed in claim 12, wherein a cross-section in a direction of the fourth spacer has an “L” shape.

18. A semiconductor device, comprising:
a substrate;
an active pattern on the substrate;
a gate structure in an upper portion of the active pattern;
a bit line structure on the active pattern, the bit line structure including a first conductive pattern, a second conductive pattern, and a capping pattern sequentially stacked in a vertical direction substantially perpendicular to an upper surface of the substrate;
a first lower spacer at least partially covering a sidewall of the first conductive pattern, the first lower spacer including silicon oxide;
a second lower spacer at least partially covering an outer sidewall of the first lower spacer, the second lower spacer including an oxide of a first metal;
a third lower spacer on an outer sidewall of the second lower spacer, the third lower spacer including a second metal that is different from the first metal;
a fourth lower spacer on the third lower spacer, the fourth lower spacer including a nitride;
an upper spacer structure contacting upper surfaces of the first to third lower spacers and an upper sidewall of the bit line structure;
a contact plug structure on the upper portion of the active pattern and adjacent to the bit line structure; and
a capacitor on the contact plug structure.

19. The semiconductor device as claimed in claim 18, wherein the first metal includes aluminum, and the second metal includes hafnium or zirconium.

20. The semiconductor device as claimed in claim 18, wherein the first conductive pattern includes polysilicon doped with impurities.
